(19) United States
(12) Patent Application Publication
(10) Pub. No.: US 2005/0243528 A1
(43) Pub. Date: Nov. 3, 2005

(54) Board pieces and composite wiring boards using the board pieces

(75) Inventor: Takashi Murayama, Kanuma-shi (JP)

Correspondence Address: OLIFF & BERRIDGE, PLC, P.O. BOX 19928, ALEXANDRIA, VA, 22320, US

(73) Assignee: Sony Chemicals Corp., Tokyo (JP)

(21) Appl. No.: 11/176,756

(22) Filed: Jul. 8, 2005

Related U.S. Application Data
(63) Continuation of application No. PCT/JP04/00026, filed on Jan. 7, 2004.

(30) Foreign Application Priority Data
Jan. 9, 2003 (JP) 2003-003438
Apr. 1, 2003 (JP) 2003-097771

(51) Int. Cl. H05K 7/02; H05K 7/06; H05K 7/08; H05K 7/10

(52) U.S. Cl. 361/760

(57) ABSTRACT

The flexible wiring board included in a board piece is exposed at both ends of the board piece, and connected to heterogeneous pieces via connecting flexible wiring boards to form a composite wiring board. Such a board piece is more convenient than storing the composite wiring board because various components can be individually stored and handled.

This is a continuation of PCT/JP2004/000026 filed Jan. 7, 2004, which claims priority to Japanese Patent Applications Nos. JP 2003-003438, filed on Jan. 9, 2003 and JP 2003-097771, filed Apr. 1, 2003. The entire disclosures of the prior applications are hereby incorporated herein by reference thereto.

### BACKGROUND

The present invention generally relates to the field of wiring boards, and more particularly board pieces comprising a rigid wiring board and a flexible wiring board as well as composite wiring boards using the board pieces.

Reference 201 in FIG. 28 represents a composite wiring board according to a related technique.

FIG. 30 is an exploded diagram showing the structure of the composite wiring board 201, in which references 271A, 272A, 271B and 272B represent rigid stacks, and reference 278 represents a flexible wiring board of a single-layer or multilayer structure.

Rigid stacks 271A, 272A, 271B and 272B consist of a stack of single-layer rigid wiring boards.

Flexible wiring board 278 is formed from a resin and has a flexible base film 211 and a wiring layer 212 provided on the base film 211.

Wiring layers 221 of rigid stacks 271A, 272A, 271B and 272B are connected to wiring layer 212 of flexible wiring board 278 and fixed to both of one surface and the opposite surface of flexible wiring board 278 at both ends.

Rigid stacks 271A, 272A, 271B and 272B are shorter than flexible wiring board 278, and rigid stacks 271A, 272A at one end and rigid stacks 271B, 272B at the other end are connected via the center portion of flexible wiring board 278.

When electronic components 245 are mounted on rigid stacks 271A, 272A, 271B and 272B as shown in FIG. 29, the electronic components 245 are connected to each other via wiring layer 212, 221.

When such a composite wiring board 201 is to be used in a portable computer, rigid stacks 271A, 272A at one end of composite wiring board 201 are placed in a housing on the keyboard side and rigid stacks 271B, 272B at the other end are placed in a housing on the liquid crystal display panel side so that the keyboard and the liquid crystal display panel can be connected via flexible wiring board 278 while the liquid crystal display panel is openable and closable. A related prior document related to is JP-A HEI 05-243738.

However, if flexible wiring board 278 is long, it is inconvenient to handle and the workability for mounting electronic components 245 is poor in the composite wiring board 201 described above. If even one of rigid stacks 271A, 272A, 271B and 272B is defective, the whole composite wiring board 201 must be discarded.

Various exemplary embodiments were made to overcome the disadvantages of the related technique described above and aims to provide a composite wiring board that is easy to handle and inexpensive.

### SUMMARY

To overcome the disadvantages described above, various exemplary embodiments provides a board piece comprising at least one flexible wiring board; a plurality of short rigid wiring boards being stacked together shorter than the flexible wiring board; and a plurality of long rigid wiring boards being stacked together longer than the short rigid wiring boards, wherein the stacked short rigid wiring boards are provided on one surface of the flexible wiring board, the stacked long rigid wiring boards are provided on the opposite surface, and the one surface of the flexible wiring board is exposed.

Various exemplary embodiments provides the board piece, wherein an end portion of the flexible wiring board is not fixed to the long rigid wiring boards.

Various exemplary embodiments provides the board piece, wherein wiring layers of adjacent ones of the short rigid wiring boards are connected via conductive bumps and wiring layers of adjacent ones of the long rigid wiring boards are connected via conductive bumps.

Various exemplary embodiments further provides a composite wiring board, comprising a connecting flexible wiring board and two or more board pieces, wherein each of the board pieces has at least one flexible wiring board; a plurality of short rigid wiring boards being stacked together shorter than the flexible wiring board; and a plurality of long rigid wiring boards being stacked together longer than the short rigid wiring boards, the stacked short rigid wiring boards are provided on one surface of the flexible wiring board, the stacked long rigid wiring boards are provided on the opposite surface, the one surface of the flexible wiring board is exposed, and the exposed portion of the flexible wiring board of each of the board pieces is connected to an end of the connecting flexible wiring board.

Various exemplary embodiments provide the composite wiring board, wherein a reinforcing film is applied across the connecting flexible wiring board and the flexible wiring board of the board piece.

Various exemplary embodiments further provide a composite wiring board, comprising a first board piece and a second board piece, wherein the first board piece has at least one flexible wiring board; a plurality of short rigid wiring boards being stacked together shorter than the flexible wiring board; and a plurality of long rigid wiring boards being stacked together longer than the short rigid wiring boards, the stacked short rigid wiring boards are provided on one surface of the flexible wiring board, the stacked long rigid wiring boards are provided on the opposite surface, the one surface of the flexible wiring board is exposed, the second board piece having at least one flexible wiring board and a plurality of rigid wiring boards being stacked together, an end of the flexible wiring board projects from an overlap between the flexible wiring board and the rigid wiring boards, both surfaces of the end of the flexible wiring board are exposed, and the exposed portion of the flexible wiring board of the first board piece and the exposed portion of the flexible wiring board of the second board piece are connected.

Various exemplary embodiments provide the composite wiring board, wherein a reinforcing film is applied across the exposed portion of the flexible wiring board of the first board piece and the exposed portion of the flexible wiring board of the second board piece.

Various exemplary embodiments provide the composite wiring board, wherein an electronic component is mounted on at least one of the board pieces.

The board piece according to a first embodiment is formed by placing an adhesive film or the like on the surfaces of the rigid wiring boards and flexible wiring board and applying heat/pressure to stack them.

Stacking is performed as follows. One or more short rigid wiring board shorter than the length of the flexible wiring board is stacked on one surface of the flexible wiring board, and one or more long rigid wiring board longer than at least the short rigid wiring board is stacked on the opposite surface.

And, at least an end portion of the flexible wiring board is unfixed to the long rigid wiring board, whereby the board piece of an exemplary embodiment is obtained. The portion of the flexible wiring board close to the short rigid wiring board may or may not be fixed to the long rigid wiring board.

The board piece of an exemplary embodiment has the structure as described above, i.e., the portion of the long rigid wiring board and the flexible wiring board projecting from the short rigid wiring board serves as a stage for connecting the flexible wiring board to another flexible wiring board.

The end portion of the flexible wiring board forming a stage can be lifted from the rigid wiring board, so that both of the flexible wiring board serving as a stage and another flexible wiring board connected thereto can be bent, whereby the stress at the junction is reduced and separation may not readily occur.

Various exemplary embodiments provide a board piece comprising a first and a second rigid parts having a rigid wiring board and a flexible wiring board longer than the first and second rigid part, wherein the first rigid part and the second rigid part are provided on one surface and the opposite surface of the flexible wiring board in such a relative position that one of the rigid parts projects from the other, the center portion of the flexible wiring board is sandwiched between the first and second rigid parts so that the flexible wiring board and the first and second rigid parts are fixed to each other at the center portion of the flexible wiring board, and the flexible wiring board projects from the center portion on both of the first rigid part and the second rigid part.

Various exemplary embodiments provide the board piece, wherein at least one of the projecting parts of the flexible wiring board on the first and second rigid parts is separable from the first or second rigid part.

Various exemplary embodiments provide the board piece, wherein the flexible wiring board comprises a base film having flexuosity and a patterned wiring layer provided on each surface of the base film.

Various exemplary embodiments provide the board piece, wherein the rigid wiring boards forming the first and second rigid parts comprises a hard board and a patterned wiring layer provided on at least one surface of the hard board and the wiring layer of the flexible wiring board and the rigid wiring board adjacent to the flexible wiring board are electrically connected to each other via conductive bumps.

Various exemplary embodiments provide the board piece, wherein at least one of the first and second rigid parts comprises two or more rigid wiring boards being stacked and the patterned wiring layers of the stacked rigid wiring boards are connected to each other via conductive bumps.

Various exemplary embodiments provide a composite wiring board, comprising a heterogeneous piece having at least a rigid wiring board; a board piece; and a connecting flexible wiring board, wherein the board piece has a first and a second rigid parts having a rigid wiring board and a flexible wiring board longer than the first and second rigid part, the first rigid part and the second rigid part are provided on one surface and the opposite surface of the flexible wiring board in such a relative position that one of the rigid parts projects from the other, the center portion of the flexible wiring board is sandwiched between the first and second rigid parts so that the flexible wiring board and the first and second rigid parts are fixed to each other at the center portion of the flexible wiring board, the flexible wiring board projects from the center portion on both of the first rigid part and the second rigid part, an end portion of the flexible wiring board of the board piece is adhered to one end of the connecting flexible wiring board, the other end of the connecting flexible wiring board is adhered to the heterogeneous piece, and the wiring layer of the flexible wiring board of the board piece and the wiring layer of the heterogeneous piece are electrically connected via the wiring layer of the connecting flexible wiring board.

Various exemplary embodiments provide the composite wiring board, wherein a reinforcing film is applied across the connecting flexible wiring board and the flexible wiring board of the board piece.

Various exemplary embodiments provide the composite wiring board, wherein an electronic component is mounted on the board piece.

The board piece according to a second embodiment has the structure as described above, i.e., an end of the flexible wiring board is not connected to the rigid wiring board forming the rigid part and can be lifted from the end of the flexible wiring board. Thus, when another flexible wiring board is connected to the end of the flexible wiring board, both flexible wiring boards can be bent together, whereby unnecessary stress is not imposed at the junction between the flexible wiring boards.

### BRIEF DESCRIPTION OF THE DRAWINGS

Various details are described below with reference to the following figures, wherein:

FIG. 1 is a sectional view for illustrating a board piece according to an example of the first embodiment of before assembly.

FIG. 2 is a sectional view of the board piece according to an example of the first embodiment of the present invention.

FIG. 3 is a sectional view (1) for illustrating a process for assembling a composite wiring board according to an example of the first embodiment of the present invention.

FIG. 4 is a sectional view (2) for illustrating a process for assembling a composite wiring board according to an example of the first embodiment of the present invention.

FIG. 5 is a sectional view (3) for illustrating a process for assembling a composite wiring board according to an example of the first embodiment of the present invention.

FIG. 6 is a sectional view (4) for illustrating a process for assembling a composite wiring board according to an example of the first embodiment of the present invention.

FIG. 7 is a sectional view (5) for illustrating a process for assembling a composite wiring board according to an example of the first embodiment of the present invention.

FIG. 8 is a sectional view of a board piece according to a second example of the first embodiment of the present invention.

FIG. 9 is a sectional view of a composite wiring board using the board piece.

FIG. 10 is a sectional view of a board piece according to a third example of the first embodiment of the present invention.

FIG. 11 is a sectional view (1) for illustrating a process for assembling a composite wiring board using the board piece.

FIG. 12 is a sectional view (2) for illustrating a process for assembling a composite wiring board using the board piece.

FIG. 13a is a plan view of a part of the board piece body and the stage according to the first embodiment of the present invention, and FIG. 13b is a plan view of an end of a connecting flexible wiring board.

FIG. 14 is a sectional view for illustrating a board piece according to an example of the second embodiment before assembly.

FIG. 15 is a sectional view of the board piece according to an example of the second embodiment of the present invention.

FIG. 16 is a sectional view for illustrating a heterogeneous piece before assembly.

FIG. 17 is a sectional view of an example of a heterogeneous piece.

FIG. 18 is a sectional view (1) for illustrating a process for assembling a composite wiring board according to an example of the second embodiment.

FIG. 19 is a sectional view (2) for illustrating a process for assembling a composite wiring board according to an example of the second embodiment.

FIG. 20 is a sectional view (3) for illustrating a process for assembling a composite wiring board according to an example of the second embodiment.

FIG. 21 is a sectional view (4) for illustrating a process for assembling a composite wiring board according to an example of the second embodiment.

FIG. 22 is a sectional view (5) for illustrating a process for assembling a composite wiring board according to an example of the second embodiment.

FIG. 23 is a sectional view of a board piece according to another example of the second embodiment of the present invention.

FIG. 24 is a sectional view of a composite wiring board using the board piece.

FIG. 25 is a sectional view (1) for illustrating a process for assembling a composite wiring board according to another example of the second embodiment.

FIG. 26 is a sectional view (2) for illustrating a process for assembling a composite wiring board according to another example of the second embodiment.

FIG. 27a is a plan view of a part of the board piece body and the stage according to the second embodiment, and FIG. 27b is a plan view of an end of a connecting flexible wiring board.

FIG. 28 is a sectional view of a composite wiring board according to a related art.

FIG. 29 is a sectional view of the composite wiring board on which electronic components have been mounted.

FIG. 30 is a sectional view of for illustrating the structure of the composite wiring board according to the related art.

### DETAILED DESCRIPTION OF EMBODIMENTS

In the first embodiment (FIGS. 1-13), references 2-4 represent board pieces, reference 8 represents a connecting flexible wiring board, references 10, 40 represent flexible wiring boards, reference 12 represents a wiring layer of flexible wiring board, references 20₁-20₃ represent short rigid wiring boards, references 22₁-22₃, 32₁-32₃ represent wiring layers of rigid wiring boards, references 24₁-24₃, 34₁-34₃ represent conductive bumps, references 30₁-30₃ represent long rigid wiring boards, references 41, 45 represent board piece bodies, references 42, 44, 46 represent stages, and reference 49 represents an electronic component.

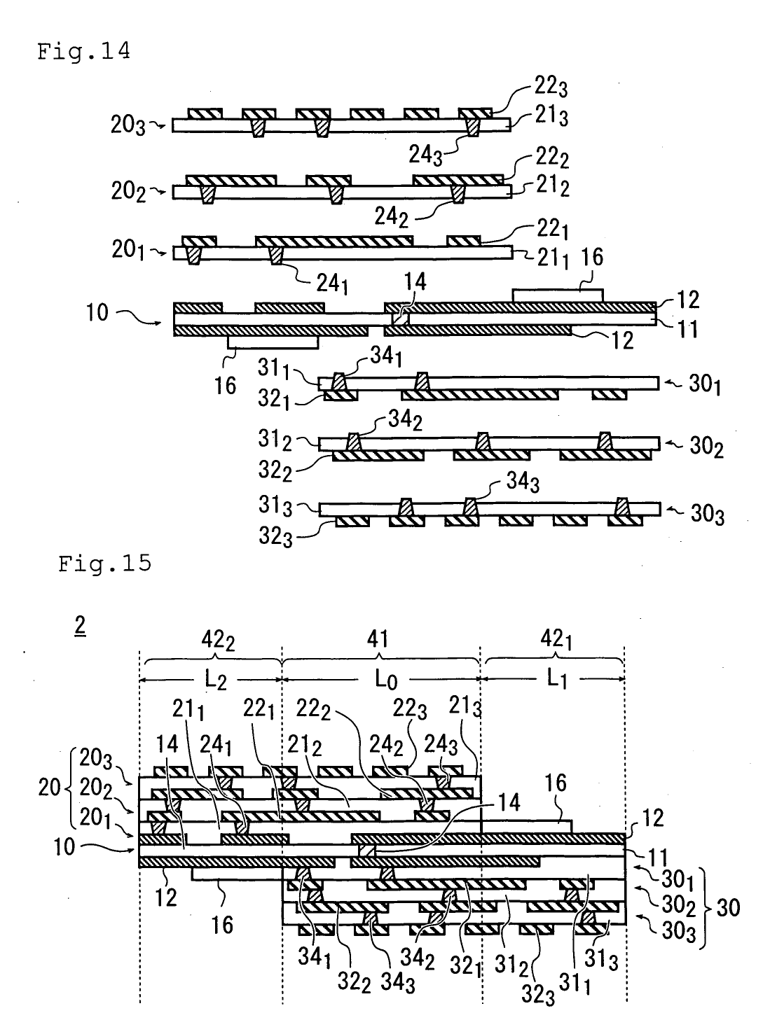

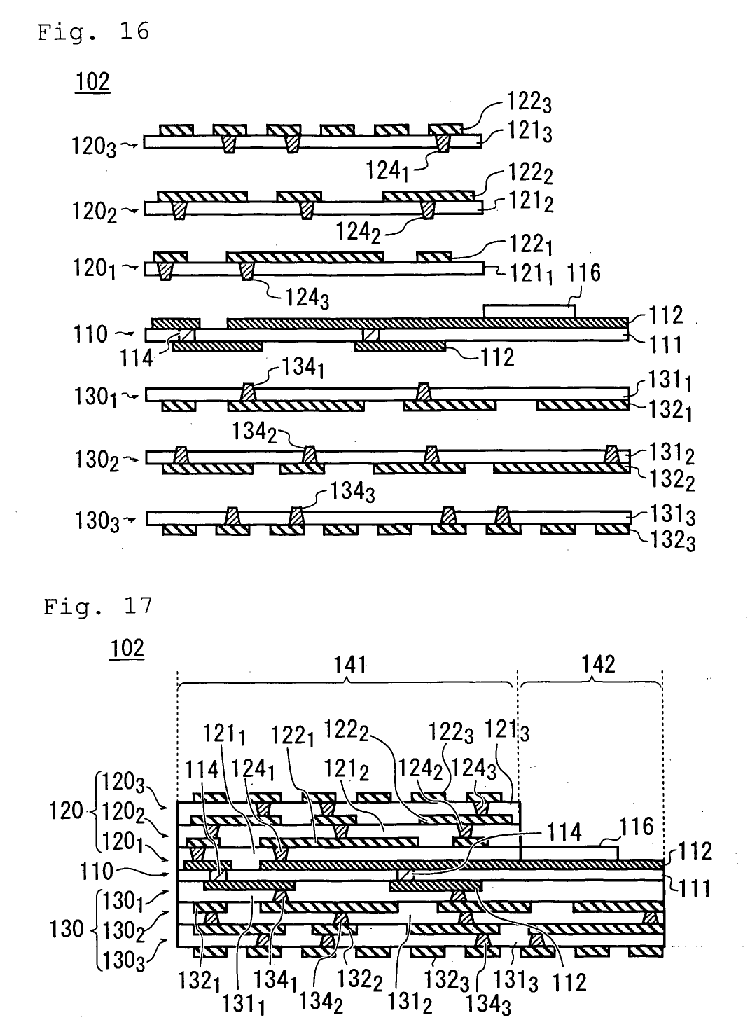

In the second embodiment (FIGS. 14-27), references 2, 3 represent board pieces, references 8A, 8B represent connecting flexible wiring boards, references 10, 40, 110, 160 represent flexible wiring boards, references 20₁-20₃, 30₁-30₃, 120₁-120₃, 130₁-130₃ represent rigid wiring boards, references 21₁-21₃, 31₁-31₃, 121₁-121₃, 131₁-131₃ represent base substrates, references 22₁-22₃, 32₁-32₃, 122₁-122₃, 132₁-132₃ represent wiring layers, references 24₁-24₃, 34₁-34₃, 124₁-124₃, 134₁-134₃ represent conductive bumps, references 41, 141 represent board piece bodies, references 42₁, 42₂,142 represent stages, reference 49 represents an electronic component, and references 102A, 102, 103 represent heterogeneous pieces.

A composite wiring board according to a first embodiment and a board piece forming a part thereof are explained with reference to drawings.

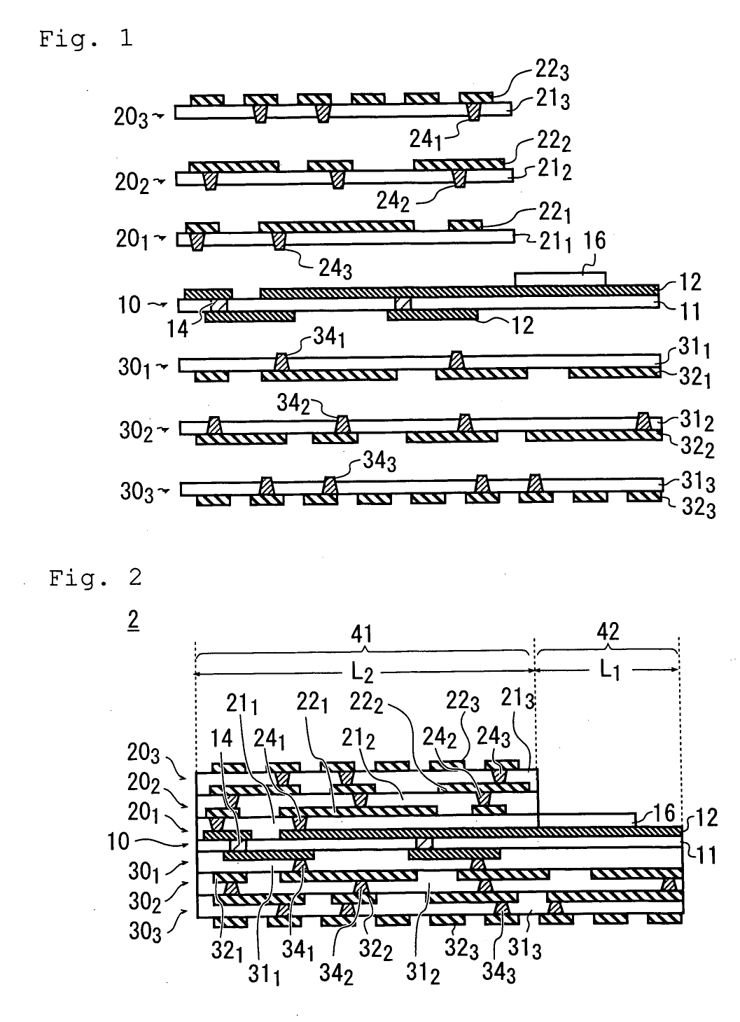

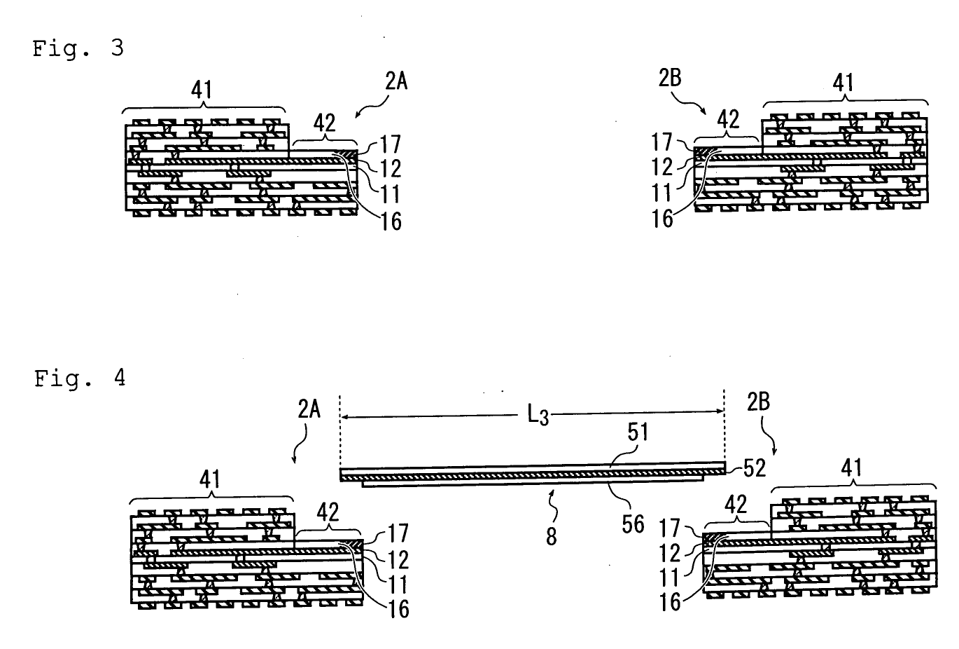

Reference 2 in FIG. 2 represents an example of a board piece, and FIG. 1 shows various components of the board piece 2 before assembly.

Board piece 2 comprises one or more flexible wiring board 10, a plurality of short rigid wiring boards 20₁-20₃ provided on one side of the flexible wiring board 10 and shorter than the flexible wiring board 10, and a plurality of long rigid wiring boards 30₁-30₃ provided on the opposite side and longer than the short rigid wiring boards 20₁-20₃.

Here, short rigid wiring boards 20₁-20₃ have the same configuration and the same length, and long rigid wiring boards 30₁-30₃ also have the same configuration and the same length.

The structures of flexible wiring board 10 and rigid wiring boards 20₁-20₃, 30₁-30₃ are explained as follows. Flexible wiring board 10 comprises a flexible base film 11 consisting of a resin film and wiring layers 12 laid on one surface and the opposite surface of the base film 11. The wiring layer 12 is formed by patterning a metal thin film in a predetermined configuration.

Wiring layers 12 on the one surface and the opposite surface are connected to each other via conductive plugs 14 inserted in through-holes. Conductive plugs 14 can be formed from metals or conductive resins.

Each of rigid wiring boards 20₁-20₃, 30₁-30₃ comprises a base substrate 21₁-21₃, 31₁-31₃, and a wiring layer 22₁-22₃, 32₁-32₃.

Wiring layer 22₁-22₃, 32₁-32₃ is formed on one side of base substrate 21₁-21₃, 31₁-31₃, and the tops of conductive bumps 24₁-24₃, 34₁-34₃ connected to wiring layer 22₁-22₃, 32₁-32₃ protrude on the opposite side before stacking. Conductive bumps 24₁-24₃, 34₁-34₃ can be formed by curing a conductive resin (conductive resin paste) or growing a metal.

Short rigid wiring boards 20₁-20₃ are provided on one side of flexible wiring board 10 and long rigid wiring boards 30₁-30₃ are provided on the opposite side.

Rigid wiring boards 20₁-20₃, 30₁-30₃ are stacked with the tops of conductive bumps 24₁-24₃, 34₁-34₃ facing flexible wiring board 10 so that the tops of conductive bumps 24₁-24₃, 34₁-34₃ comes into contact with wiring layers 12, 22₁-22₃, 32₁-32₃, thereby allowing electric connection between wiring layers 22₁-22₃, 32₁-32₃ of rigid wiring boards 20₁-20₃, 30₁-30₃ or between wiring layers 22₁, 32₁ of rigid wiring boards 20₁, 30₁ and wiring layer 12 of flexible wiring board 10.

Wiring layers 12, 22₁-22₃, 32₁-32₃ of flexible wiring board 10 and rigid wiring boards 20₁-20₃, 30₁-30₃ are divided into a plurality of lines apart from each other and those lines at predetermined locations are connected to each other.

Adhesive films are inserted between rigid wiring boards 20₁-20₃, 30₁-30₃ and between rigid wiring boards 20₁, 30₁ and flexible wiring board 10 so that rigid wiring boards 20₁-20₃, 30₁-30₃ and flexible wiring board 10 are at least partially or wholly mechanically connected to each other via the adhesive film.

Flexible wiring board 10 and long rigid wiring boards 30₁-30₃ laterally project from the lateral sides of short rigid wiring boards 20₁-20₃, whereby the projection forms a stage 42.

Long rigid wiring boards 30₁-30₃ and flexible wiring board 10 except for stage 42 and short rigid wiring boards 20₁-20₃ form a board piece body.

If the length of stage 42 in the direction of the projection from board piece body 41 is expressed by symbol L₁ and the length of board piece body 41 in the same direction is expressed by symbol L₂, the length L₁ of stage 42 is shorter than the length L₂ of board piece body 41 to improve workability (L₁<L₂).

The part of flexible wiring board 10 included in board piece body 41 is fixed to rigid wiring boards 20₁, 30₁ adjacent thereto with an adhesive film or the like, while the part included in stage 42 is not fixed to rigid wiring board 30₁ at least at the end portion but can be freely lifted.

A cover film 16 is applied on the one surface of the part of flexible wiring board 10 included in stage 42 except for a part. Here, cover film 16 is applied except for end portion.

Cover film 16 is not placed on the end portion of flexible wiring board 10 and the tops of wiring layers 12 and base film 11 are exposed.

FIG. 13a is a partial plan view of board piece 2 of the structure described above, showing a part of board piece body 41 and stage 42.

Next, a process for preparing a composite wiring board comprising board piece 2 as a component is explained.

References 2A and 2B in FIG. 3 represent board pieces having the same structure as that of board piece 2 described above, in which wiring layer 12 of flexible wiring boards 10 in these two board pieces 2A, 2B is exposed at the end of stage 42.

First, an anisotropically conductive film 17 is placed on the surface of the exposed portion of wiring layer 12 of each board piece 2A, 2B. Base film 11 at the opposite surface of at least this exposed portion is not fixed to rigid wiring board 30₁ adjacent to the opposite surface.

Reference 8 in FIG. 4 represents a connecting flexible wiring board distinct from flexible wiring board 10 described above. This connecting flexible wiring board 8 has a wiring layer 52 provided on at least one surface of a base film 51 and a cover film 56 provided on the surface of wiring layer 52 except for both ends. Both ends of wiring layer 52 are exposed.

FIG. 13b is a plan view of an end of connecting flexible wiring board 8, and wiring layer 52 of this flexible wiring board 8 is patterned in a configuration and a position corresponding to the pattern of wiring layer 12 on stage 42.

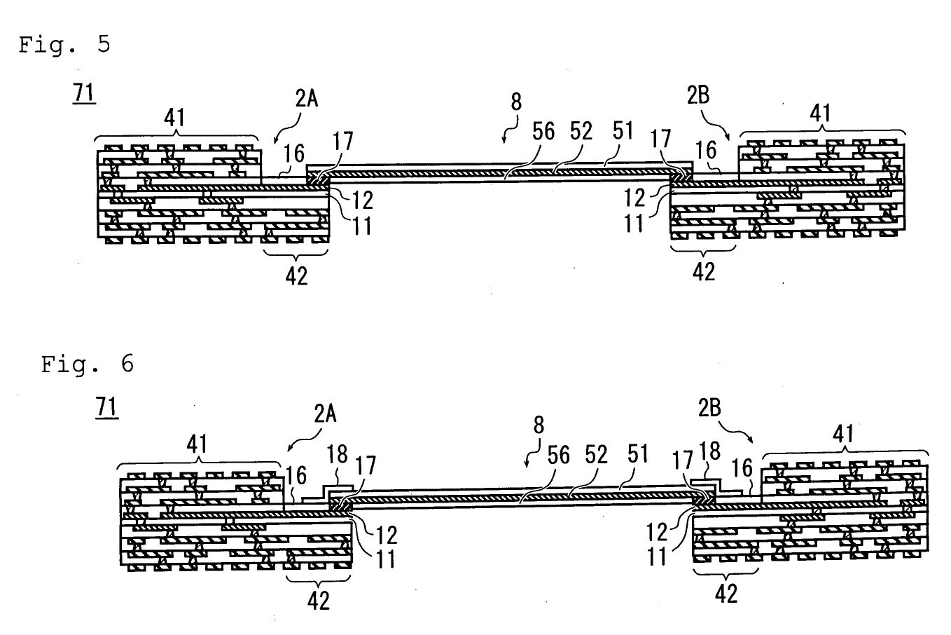

When the exposed portion of this wiring layer 52 is pressed against anisotropically conductive film 17 of board piece 2A, 2B and heat and pressure are applied, board piece 2A, 2B and connecting flexible wiring board 8 are electrically and mechanically connected to each other as shown in FIG. 5 to obtain a composite wiring board 71.

Thus, wiring layer 52 of connecting flexible wiring board 8 and wiring layer 12 of flexible wiring board 10 of board piece 2A, 2B are electrically connected to each other so that wiring layers 12, 22₁-22₃, 32₁-32₃ of one board piece 2A and wiring layers 12, 22₁-22₃, 32₁-32₃ of the other board piece 2B are connected to each other via wiring layer 52 of connecting flexible wiring board 8.

During the step of pressing connecting flexible wiring board 8 against stage 42, flexible wiring board 10 on the top of stage 42 is closely contacted with rigid wiring board 30, and pressed against stacked rigid wiring boards 30₁-30₃. Thus, flexible wiring board 10 on the top of stage 42 is immobilized during pressing to prevent any error in connecting flexible wiring layers 12, 52.

In this composite wiring board 71, flexible wiring boards 10 of board pieces 2A, 2B and connecting flexible wiring board 8 are flexible so that connecting flexible wiring board 8 can be bent while maintaining connection between wiring layer 12 of flexible wiring board 10 of board pieces 2A, 2B and wiring layers 22₁, 32₁ of rigid wiring boards 20₁, 30₁ or electric connection between wiring layers 12, 52 of flexible wiring boards 8, 10.

When connecting flexible wiring board 8 is bent, the end portion of flexible wiring boards 10 of each board piece 2A, 2B on stage 42 is also bent, thereby reducing the stress produced between flexible wiring boards 10, 8 or between flexible wiring board 10 and rigid wiring boards 20₁, 30₁.

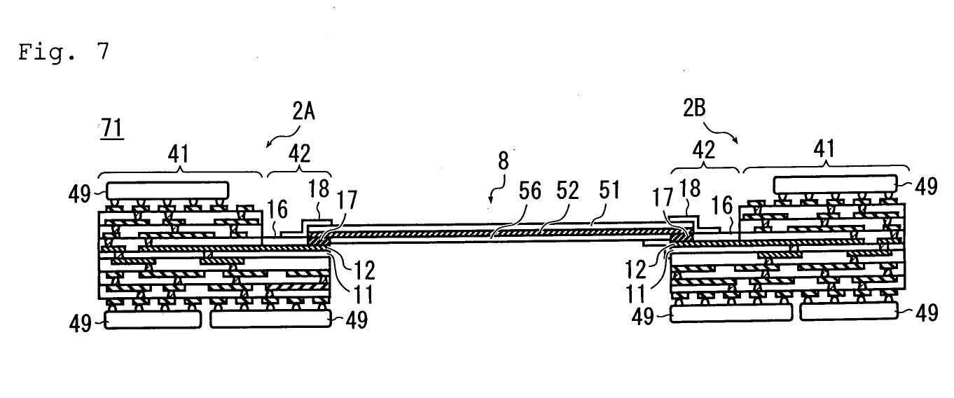

Then, wiring layers 12, 52 are electrically connected to each other and a reinforcing film 18 is then applied across the end portion of flexible wiring board 10 on stage 42 and the end portion of connecting flexible wiring board 8 as shown in FIG. 6, whereby flexible wiring boards 8, 10 are mechanically firmly connected via reinforcing film 18.

As a result, flexible wiring boards 8, 10 are not separated even if connecting flexible wiring board 8 is considerably bent.

No reinforcing film is applied across the opposite surface of connecting flexible wiring board 8 and the lateral sides of long rigid wiring boards 30₁-30₃ so that at least the end portion of the part of flexible wiring board 10 included in stage 42 can be separated from rigid wiring board 30₁.

Thus, the end of flexible wiring board 10 can also be bent, whereby it becomes further difficult to separate flexible wiring boards 8, 10.

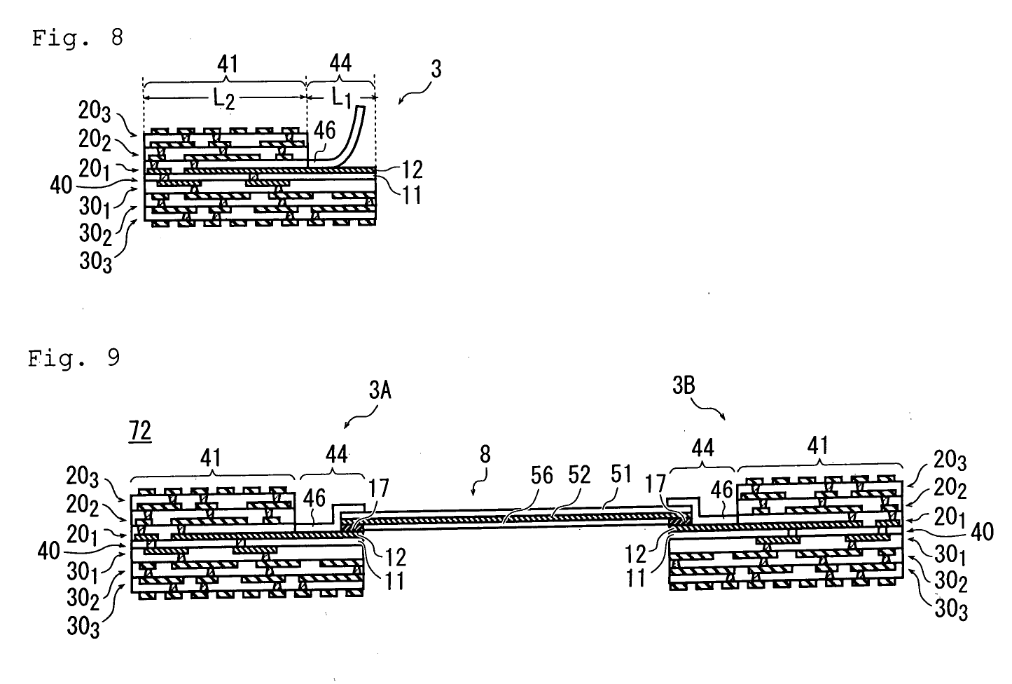

Then, an electronic component 49 is set on each board piece 2A, 2B as shown in FIG. 7, and the terminal of electronic component 49 is connected to the outermost wiring layers 22₃, 32₃ of rigid wiring board 20₃, 30₃, whereby electronic component 49 is mounted on board piece 2A, 2B.

In this state, electronic component 49 is connected to wiring layer 52 of connecting flexible wiring board 8 or electronic components 49 are connected to each other via wiring layers 12, 22₁-22₃, 32₁-32₃, conductive bumps 24₁-24₃, 34₁-34₃ of board pieces 2A, 2B.

When one of board pieces 2A, 2B connected via connecting flexible wiring board 8 is connected to a power source or other electronic circuits, each electronic component 49 is connected to the other electronic circuits, such as a power source and the like.

Base films 11, 51 and cover films 16, 56 of the flexible wiring board 10, 8 described above are polyimide films of ten to several tens of micrometers.

Wiring layers 12, 52, 22₁-22₃, 32₁-32₃ consist of a copper foil having a thickness of ten to several tens of micrometers patterned in a predetermined configuration and are bent with base films 11, 51 or cover films 16, 56 to ensure the flexibility of flexible wiring boards 8, 10.

On the other hand, base substrates 21₁-21₃, 31₁-31₃ of rigid wiring boards 20₁-20₃, 30₁-30₃ are inflexible thin plates having a thickness of about 50-500 μm made from glass epoxy resin or the like. Once electronic component 49 is mounted, therefore, no stress is imposed between the terminal of electronic component 49 and wiring layers 22₃, 32₃.

Next, another exemplary embodiment is explained. Reference 3 in FIG. 8 represents a board piece according to a second example, which differs from board piece 2 according to the first example in that cover film 46 of flexible wiring board 40 is longer than the length of stage 44.

The end portion of cover film 46 is not adhered to wiring layer 12 or base film 11, and the top of wiring layer 12 is exposed at that part.

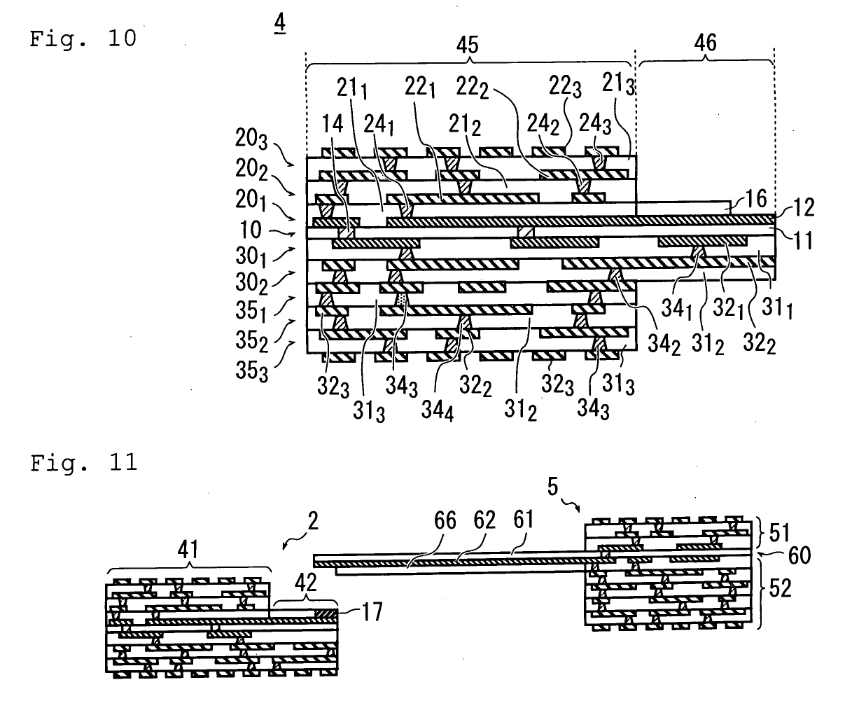

References 3A and 3B in FIG. 9 represent two board pieces of such a structure, and an anisotropically conductive film 17 is placed on the exposed portion of wiring layer 12 of each board piece 3A, 3B and a connecting flexible wiring board 8 is applied, and then the floating portion of cover film 46 is applied on connecting flexible wiring board 8, thereby forming a composite wiring board 72 according to the second example.

Thus, the floating portion of cover film 46 from base film 11 or the like is used as a reinforcing film in this composite wiring board 72. The floating portion of cover film 46 is here applied on base film 51 of connecting flexible wiring board 8. The opposite end to the floating portion may be terminated at the end of board piece body 41 or extended into board piece body 41.

The length L₁ of stage 44 is also shorter than the length L₂ of board piece body 41 in this board piece 3.

Although the length of long rigid wiring board 30₁-30₃ is equal to or longer than the length of flexible wiring board 10 in board pieces 2, 3 described above, various exemplary embodiments is not limited to such a configuration.

Reference 4 in FIG. 10 represents a board piece according to a third example. In this board piece 4, one or more rigid wiring board 30₁, 30₂ having the same length as that of flexible wiring board 10 is placed on the opposite surface of flexible wiring board 10, and one or more rigid wiring board 35₁-35₃ having the same length as that of short rigid wiring board 20₁-20₃ is placed on the surface of the lowermost rigid wiring board 30₂.

Reference 46 represents a stage formed by a part of flexible wiring board 10 and long rigid wiring boards 30₁, 30₂ projecting from short rigid wiring boards 20₁-20₃ and rigid wiring boards 35₁-35₃ provided at the bottom. Reference 45 represents a board piece body comprising rigid wiring board 20₁-20₃, 30₁, 30₂ and 35₁-35₃ and flexible wiring board 10 except for stage 46.

Again in this board piece 4, at least end portion of flexible wiring board 10 is not connected to rigid wiring board 30₁, but can be lifted.

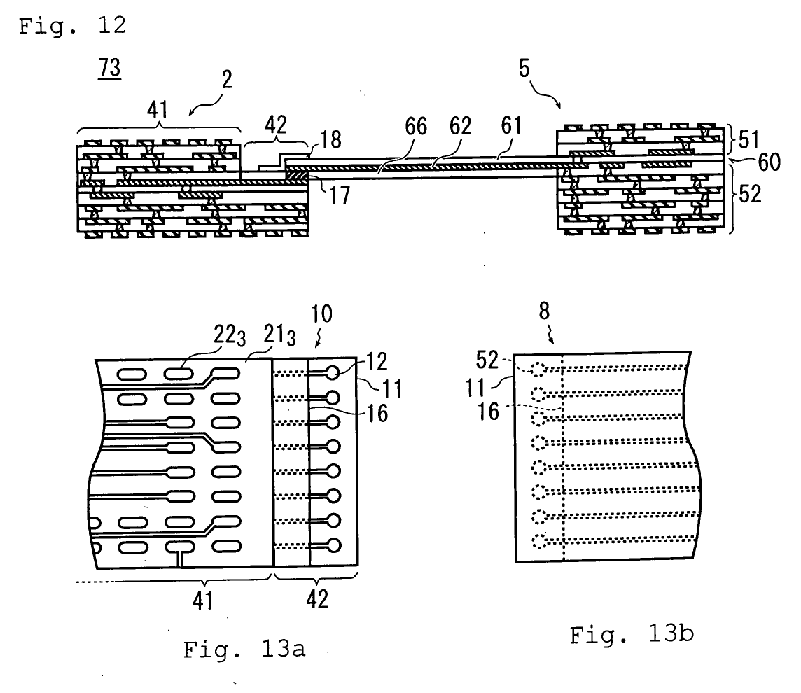

Reference 5 in FIG. 11 represents a heterogeneous board piece which is a different type from board pieces 2-4 according to the first to third examples described above, in which one end of flexible wiring board 60 is fixed to rigid wiring boards 51, 52 stacked on the top and the bottom thereof and the other end projects from rigid wiring boards 51, 52.

This flexible wiring board 60 comprises a stack of a base film 61, a wiring layer 62 and a cover film 66, and wiring layer 62 is exposed at the end of the projection.

Reference 2 in the same figure represents a board piece according to the first example of described above, wherein an anisotropically conductive film is applied on wiring layer 12 located on stage 42. When the exposed portion of wiring layer 62 of heterogeneous board piece 5 is pressed against anisotropically conductive film 17 and heat and pressure are applied, an end of flexible wiring board 60 of heterogeneous board piece 5 is fixed to flexible wiring board 10 on stage 42, as shown in FIG. 12. Wiring layers 12, 62 of flexible wiring boards 10, 60 are electrically connected via anisotropically conductive film 17 to obtain a composite wiring board 73 according to the third example of various exemplary embodiments as shown in FIG. 12.

Again in this composite wiring board 73, a reinforcing film 18 is applied across the end portion of flexible wiring board 10 on stage 42 and the end portion of connecting flexible wiring board 60, whereby flexible wiring boards 8, 10 are mechanically firmly connected to each other via reinforcing film 18.

In this manner, board pieces of various exemplary embodiments can be freely combined with heterogeneous board pieces to form composite wiring boards. Any composite wiring board is included in various exemplary embodiments so far as a board piece of various exemplary embodiments is used.

The electronic component 49 described above may be mounted after a composite wiring board of various exemplary embodiments has been assembled from board pieces or the electronic component may be mounted on board pieces 2, 3 and then connected to a connecting flexible wiring board and other board pieces to assemble a composite wiring board.

Although the flexible wiring board 8 used for connection and the flexible wiring boards 10, 40 forming the stages 42, 44 were single-layer components, a plurality of flexible wiring boards may be stacked.

A composite wiring board according to a second embodiment and a board piece forming a part thereof are explained with reference to drawings.

Reference 2 in FIG. 15 represents an example of a board piece of various exemplary embodiments, and FIG. 14 individually shows various components of the board piece 2 before assembly.

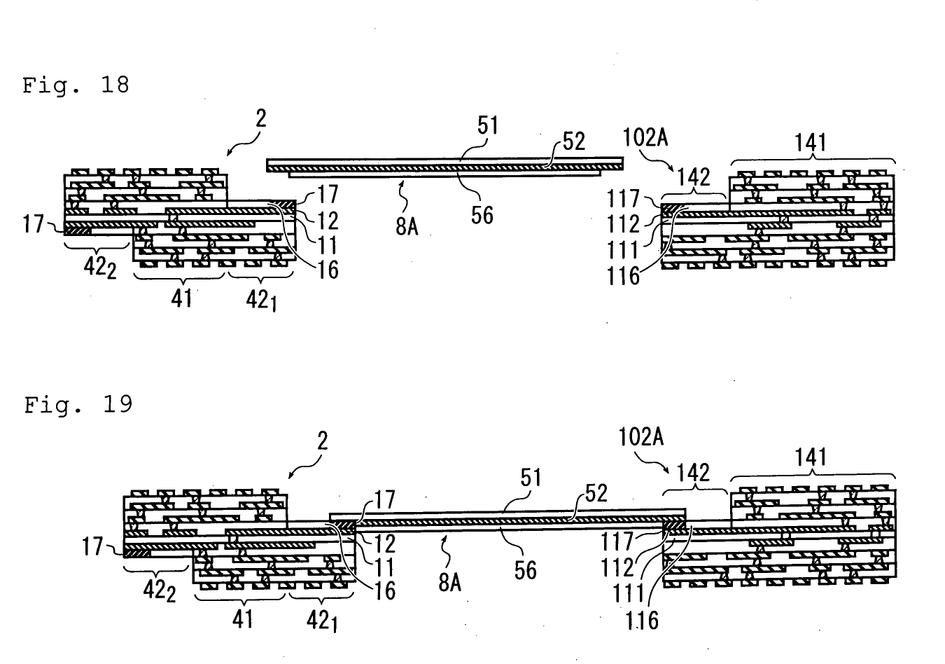

Reference 102 in FIG. 17 represents a heterogeneous piece having a different structure from that of board piece 2 of various exemplary embodiments. This heterogeneous piece 102 and heterogeneous pieces described below are used in combination with board piece 2 to form a composite wiring board. FIG. 16 individually shows various components of the heterogeneous piece 102 before assembly.

Referring to FIG. 14 to FIG. 17, board piece 2 of various exemplary embodiments and heterogeneous piece 102 used in combination with the board piece 2 comprise one or more flexible wiring boards 10, 110; a plurality of rigid wiring boards 20₁-20₃, 120₁-120₃ provided on one surface of the flexible wiring boards 10, 110; and a plurality of rigid wiring boards 30₁-30₃, 130₁-130₃ provided on the opposite surface.

Rigid wiring boards 20₁-20₃, 120₁-120₃ provided on the one surface of flexible wiring boards 10, 110 have the same configuration and the same length; and rigid wiring boards 30₁-30₃, 130₁-130₃ provided on the opposite surface also have the same configuration and the same length.

Rigid wiring boards 20₁-20₃, 120₁-120₃ provided on the one surface and rigid wiring boards 30₁-30₃, 130₁-130₃ provided on the opposite surface are stacked with both ends flushed not to be projected from each other.

References 20, 120 in FIG. 15 and FIG. 17 represent a first rigid part consisting of stacked rigid wiring boards 20₁-20₃, 120₁-120₃ on the one surface; and references 30, 130 represent a second rigid part consisting of stacked rigid wiring boards 30₁-30₃, 130₁-130₃ provided on the opposite surface.

The structures of rigid wiring boards 20₁-20₃, 30₁-30₃, 120₁-120₃, 130₁-130₃ are explained as follows. Each rigid wiring board 20₁-20₃, 30₁-30₃, 120₁-120₃, 130₁-130₃ comprises a base substrate 21₁-21₃, 31₁-31₃, 121₁-121₃, 131₁-131₃ and a wiring layer 22₁-22₃, 32₁-32₃, 122₁-122₃, 132₁-132₃.

Wiring layers 22₁-22₃, 32₁-32₃, 122₁-122₃, 132₁-132₃ are provided on one side of base substrate 21₁-21₃, 31₁-31₃, 121₁-121₃, 131₋131₃ and before stacking, the tops of conductive bumps 24₁-24₃, 34₁-34₃, 124₁-124₃, 134₁-134₃ connected at the bottom to each wiring layer 22₁-22₃, 32₁-32₃, 122₁-122₃, 132₁-132₃ penetrate through base substrate 21₁-21₃, 31₁-31₃, 121₁-121₃, 131₁-131₃ to protrude on the opposite side.

Conductive bumps 24₁-24₃, 34₁-34₃, 124₁-124₃, 134₁-134₃ can be formed by curing a conductive resin (conductive resin paste) or growing a metal.

In rigid wiring boards 20₁-20₃, 30₁-30₃, 120₁-120₃, 130₁-130₃ forming first and second rigid parts 20, 30, 120, 130, wiring layers 22₁-22₃, 32₁-32₃, 122₁-122₃, 132₁-132₃ of adjacent rigid wiring boards 20₁-20₃, 30₁-30₃, 120₁-120₃, 130₁-130₃ and the tops of conductive bumps 24₁-24₃, 34₁-34₃, 124₁-124₃, 134₁-134₃ are contacted and electrically connected with each other.

An adhesive is inserted between rigid wiring boards 20₁-20₃, 30₁-30₃, 120₁-120₃, 130₁-130₃ so that rigid wiring boards 20₁-20₃, 30₁-30₃, 120₁-120₃, 130₁-130₃ are adhered to each other with the adhesive and fixed to each other.

Then, the flexible wiring board 10 included in the board piece 2 of various exemplary embodiments has a length longer than the length of each rigid wiring board 20₁-20₃, 30₁-30₃, and first rigid part 20 on one surface is placed at one end of flexible wiring board 10 while second rigid part 30 on the opposite surface is placed at the opposite end. Thus, both ends of flexible wiring board 10 are exposed on opposite sides to each other.

The sum of the length of one rigid wiring board 20₁-20₃ forming first rigid part 20 and the length of one rigid wiring board 30₁-30₃ forming second rigid part 30 is longer than the length of flexible wiring board 10.

Therefore, first rigid part 20 and second rigid part 30 overlap at the center portion of flexible wiring board 10, and the center portion of flexible wiring board 10 is sandwiched between first and second rigid parts 20, 30.

Reference 41 in FIG. 15 represents a board piece body consisting of an overlap between first and second rigid parts 20, 30 and the part of flexible wiring board 10 sandwiched between first and second rigid parts 20, 30, and references 42₁, 42₂ represent stages consisting of a part of first and second rigid parts 20, 30 and flexible wiring board 10 projecting from board piece body 41.

Flexible wiring board 10 of board piece 2 of various exemplary embodiments and flexible wiring board 110 of heterogeneous piece 102 used in combination with the board piece 2 comprise a base film 11, 111 including a resin film; and a wiring layer 12, 112 provided on each of one surface and the opposite surface of base film 11, 111. Wiring layers 12, 112 are formed by patterning a metal thin film, such as a copper foil in a predetermined configuration.

As an example of this patterning, wiring layers 12, 112 of flexible wiring boards 10, 110 as well as wiring layers 22₁-22₃, 32₁-32₃, 122₁-122₃, 132₁-132₃ of rigid wiring boards 20₁-20₃, 30₁-30₃, 120₁-120₃, 130₁-130₃ are divided into a plurality of lines.

Through-holes are formed in base films 11, 111, and the parts of wiring layers 12, 112 located on the one surface and the opposite surface of base films 11, 111 are electrically connected to each other via conductive plugs 14, 114 inserted in through-holes. Conductive plugs 14, 114 can be formed from metals or conductive resins.

In the part located within board piece body 41, first and second rigid parts 20, 30 are electrically connected to each other via conductive bumps 24₁, 34₁ exposed on the top of them and contacted with wiring layer 12 of flexible wiring board 10.

An adhesive is inserted between flexible wiring board 10 in the part of board piece body 41 and first and second rigid parts 20, 30 so that flexible wiring board 10 and first and second rigid parts 20, 30 are adhered to each other.

In stages 42₁, 42₂, however, flexible wiring board 10 and first and second rigid parts 20, 30 are not adhered at least at the end portion of flexible wiring board 10 and a part extending over a distance from the end of flexible wiring board 10 can be lifted from stacks 20, 30.

Thus, the part of flexible wiring board 10 that can be lifted can be separated from first and second rigid parts 20, 30.

A cover film 16 is applied on the top of wiring layer 12 at least in the part of flexible wiring board 10 included in stages 42₁, 42₂, and wiring layer 12 is covered with cover film 16 except for an exposed portion thereof.

Next, heterogeneous piece 102 used in combination with board piece 2 of various exemplary embodiments is explained. In heterogeneous piece 102, rigid wiring boards 120₁-120₃ provided on one surface of flexible wiring board 110 are shorter than the length of flexible wiring board 110, while rigid wiring boards 130₁-130₃ provided on the opposite surface are as long as the length of flexible wiring board 110.

A first rigid part 120 consisting of short rigid wiring boards 120₁-120₃ is provided at an end of flexible wiring board 110. Thus, the other end of flexible wiring board 110 projects from the first rigid part 120.

A second rigid part 130 consisting of long rigid wiring boards 130₁-130₃ have both ends flush with both ends of flexible wiring board 110.

Reference 141 in FIG. 17 represents a board piece body comprising an overlap between a long second rigid part 130 and a first rigid part 120; a short first rigid part; and a part of flexible wiring board 110 sandwiched between first and second rigid parts 120, 130. Reference 142 represents a stage consisting of a part of long stack 130 and flexible wiring board 110 projecting from board piece body 141.

A part of wiring layer 112 is exposed near an end of a part of flexible wiring board 110 included in stage 142, and the other part is equipped with a cover film 116 and covered with the cover film 116.

In the part included in board piece body 141, flexible wiring board 110 and first and second rigid parts 120, 130 are mechanically connected to each other with an adhesive.

In the part of flexible wiring board 110 included in stage 142, however, at least an end of flexible wiring board 110 is not adhered to second rigid part 130 so that the end of flexible wiring board 110 can be lifted from stack 130. Thus, the end of flexible wiring board 110 can be separated from second rigid part 130.

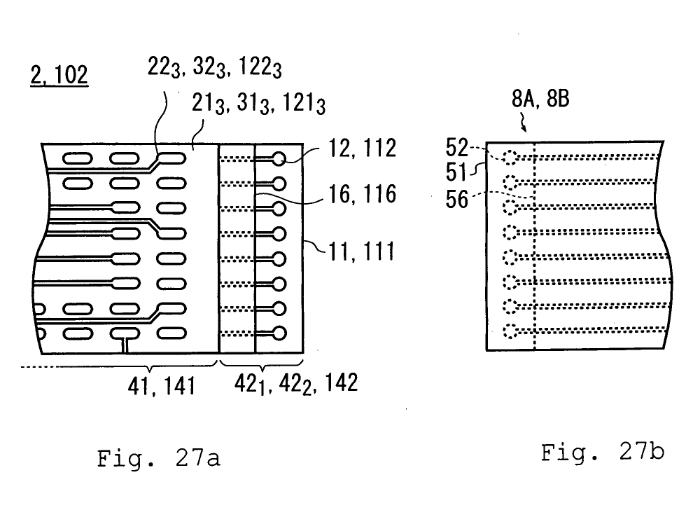

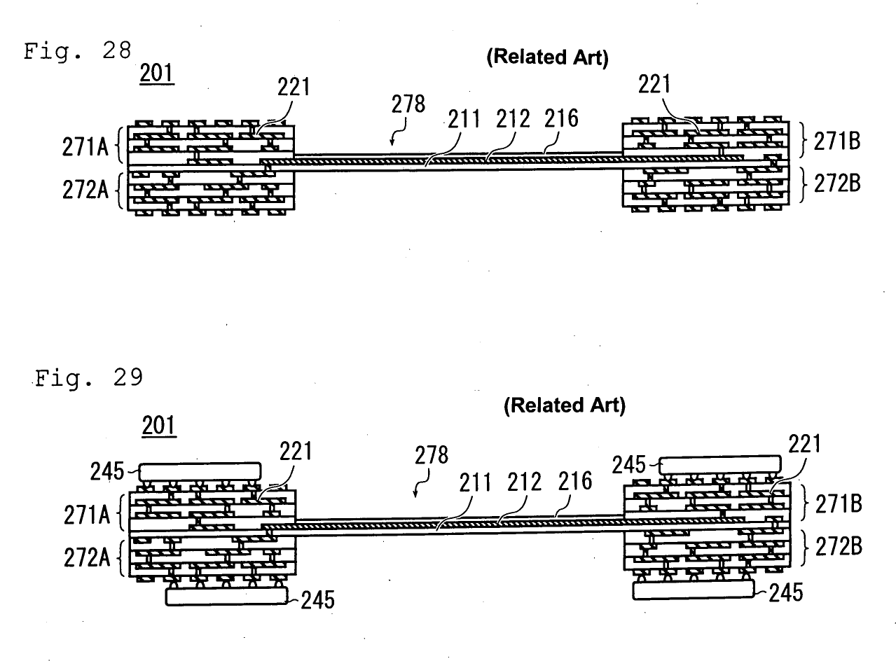

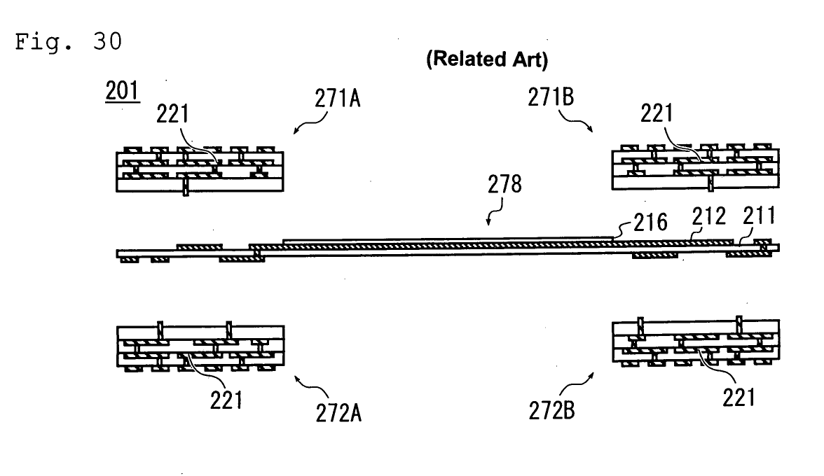

FIG. 27a is a plan view of an end of stage 42₁, 42₂, 142 of board piece 2 or heterogeneous piece 102 of the structure described above and also shows a part of board piece body 41, 141. Here, an end portion of cover film 16, 116 is removed and ends of a plurality of wiring layers 12, 112 are exposed.

Next, a process for preparing an example of a composite wiring board of various exemplary embodiments using board piece 2 and heterogeneous piece 102 is explained.

Reference 102A in FIG. 18 and reference 102B described below represent heterogeneous pieces having the same structure as that of the heterogeneous piece 102 described above, and reference 8A and reference 8B described below represent independent connecting flexible wiring boards other than components of board piece 2 or heterogeneous pieces 102A, 102B.

Connecting flexible wiring board 8A (and 8B) comprises a stack of a base film 51, a patterned wiring layer 52 and a cover film 56, and wiring layer 52 is exposed at both ends of connecting flexible wiring board 8A, 8B by patterning cover film 56.

FIG. 27b is a plan view of an end of connecting flexible wiring board 8A (and flexible wiring board 8B described below).

The end of this connecting flexible wiring board 8A is placed on stage 42₁ of board piece 2 or stage 142 of heterogeneous piece 102A, and the end of connecting flexible wiring board 8A is superimposed on the end of flexible wiring board 10, 110 forming a part of stage 42₁, 142.

A plurality of exposed portions of wiring layer 52 of connecting flexible wiring board 8A are located at the positions corresponding to the exposed portions of wiring layer 12, 112 of flexible wiring board 10, 11 of board piece 2 or heterogeneous piece 102A.

First, an anisotropically conductive film 17, 117 is applied on the surfaces of the exposed portions of wiring layer 12 included in stages 42₁, 42₂ of board piece 2 and the surfaces of the exposed portions of wiring layer 112 included in stage 142 of heterogeneous piece 102A.

The exposed portions of wiring layer 52 of connecting flexible wiring board 8A and the exposed portions of wiring layers 12, 112 included in stages 42₁, 142 are aligned to overlap each other and connecting flexible wiring board 8A is closely contacted on anisotropically conductive films 17, 117 on stage 42₁, 142, and heat and pressure are applied, whereby wiring layers 12, 112 of board piece 2 and heterogeneous piece 102A are electrically connected to each other via wiring layer 52 of connecting flexible wiring board 8A as shown in FIG. 19.

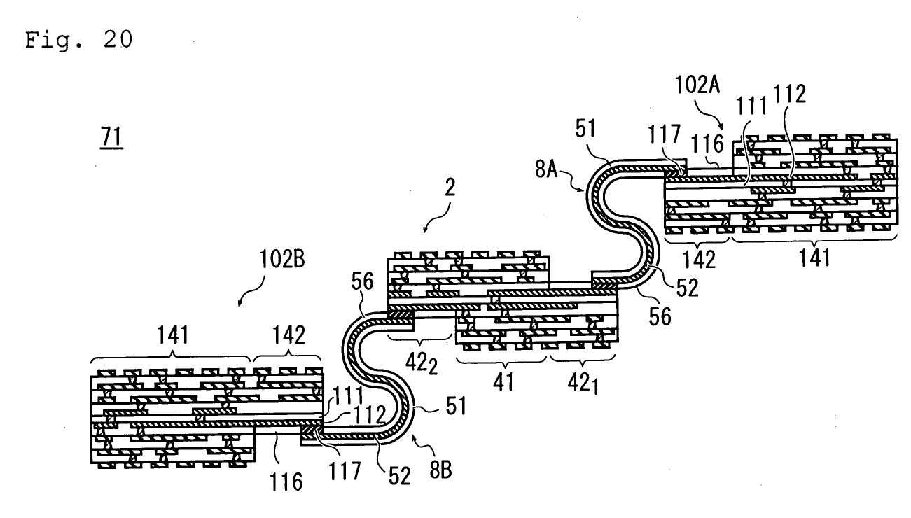

Then, the remaining stage 42₁ of board piece 2 of various exemplary embodiments and another heterogeneous piece 102B are connected via another connecting flexible wiring board 8B by the same procedure as described above as shown in FIG. 20 to obtain a composite wiring board 71 according to a first example of various exemplary embodiments.

In this composite wiring board 71, heterogeneous pieces 102A, 102B are electrically connected to each other via connecting flexible wiring boards 8A, 8B and board piece 2.

During the step of pressing the ends of connecting flexible wiring boards 8A, 8B against stages 42₁, 42₂, the ends of flexible wiring boards 8A, 8B are closely contacted with stages 42₁, 42₂ and pressed against each stage 42₁, 42₂. Thus, the pressed portions of flexible wiring boards 8A, 8B are immobilized to prevent any connection error.

Flexible wiring board 10 of board piece 2 and connecting flexible wiring boards 8A, 8B are flexible and flexuous so that flexible wiring boards 10, 8A, 8B in composite wiring board 71 can be bent while maintaining electric connection between flexible wiring boards 10, 8A, 8B.

Both ends of flexible wiring board 10 of board piece 2 on which at least anisotropically conductive film 17 is applied are not adhered to first and second rigid parts 20, 30, but the ends of flexible wiring board 10 can be lifted.

When connecting flexible wiring boards 8A, 8B are bent, therefore, an end portion of flexible wiring board 10 forming a part of board piece 2 can be separated from rigid wiring boards 20₁, 30₁ and bent together. Thus, the stress produced at the junction between connecting flexible wiring boards 8A, 8B and flexible wiring board 10 is reduced.

Here, the part of flexible wiring board 110 of heterogeneous pieces 102A, 102B included in stage 142 is not fixed to second rigid part 130 located at the opposite surface, either, so that it is bent with connecting flexible wiring boards 8A, 8B and the stress produced at the junction between flexible wiring boards 8A, 8B, 110 is reduced.

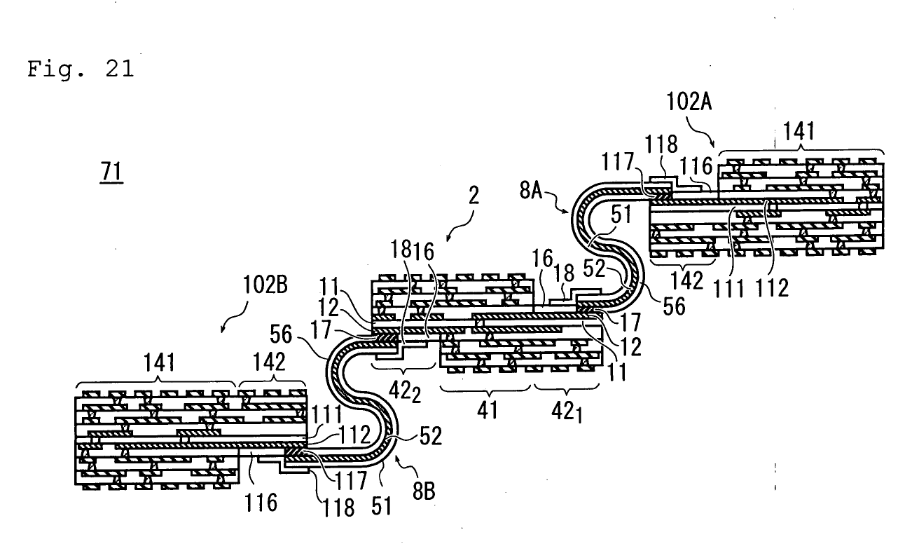

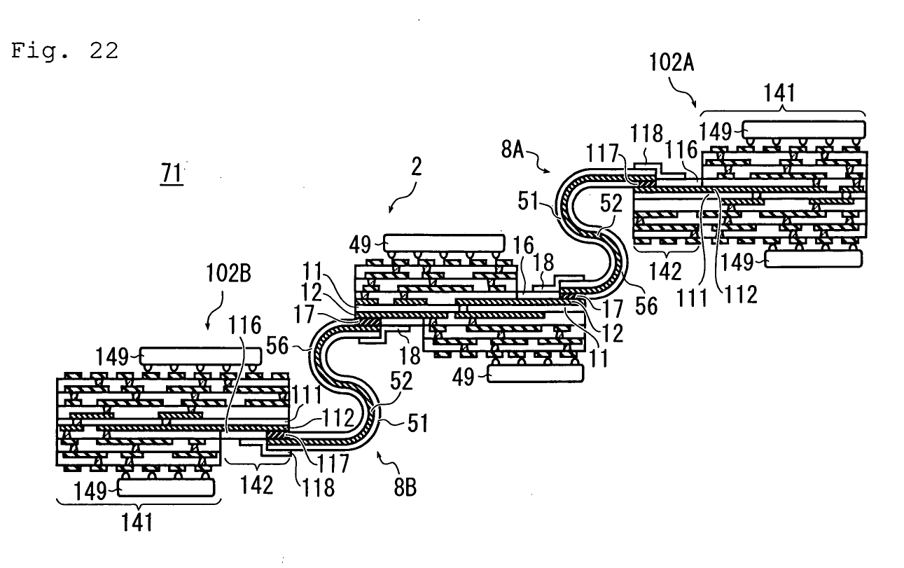

After board piece 2 and heterogeneous pieces 102A, 102B are electrically connected via connecting flexible wiring boards 8A, 8B, a reinforcing film 18 is applied across the end portion of flexible wiring board 10 of board piece 2 and the end portion of connecting flexible wiring boards 8A, 8B as shown in FIG. 21.

Similarly, a reinforcing film 118 is applied across flexible wiring board 110 of heterogeneous pieces 102A, 102B and connecting flexible wiring boards 8A, 8B.

Here, reinforcing film 118 was applied on cover films 16, 116, 56 of flexible wiring boards 10, 110, 8A, 8B.

Reinforcing films 18, 118 ensure firm mechanical connection between flexible wiring board 10 of board piece 2 and connecting flexible wiring boards 8A, 8B and between heterogeneous pieces 102A, 102B and connecting flexible wiring boards 8A, 8B.

As a result of connection between flexible wiring boards 10, 110, 8A, 8B via reinforcing film 18, flexible wiring boards 10, 110 of board piece 2 or heterogeneous piece 102 cannot be separated from connecting flexible wiring boards 8A, 8B even if connecting flexible wiring boards 8A, 8B are considerably bent.

No reinforcing film is applied between connecting flexible wiring boards 8A, 8B and first and second rigid parts 20, 30, 120, 130 to allow an end portion of flexible wiring board 10, 110 of board piece 2 or heterogeneous piece 102 to be lifted.

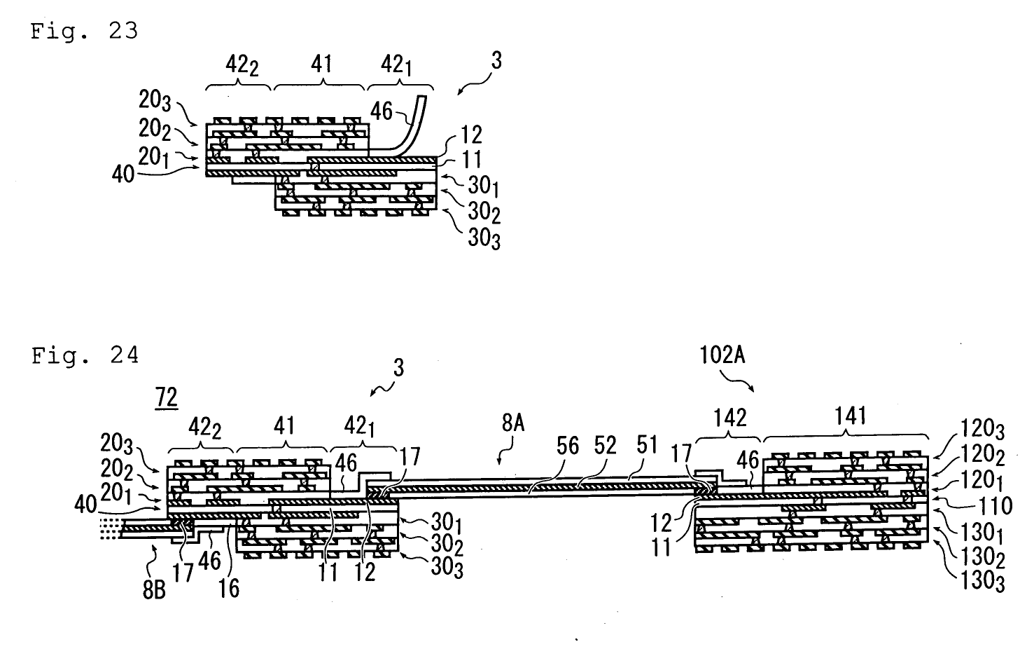

Then, an electronic component 49 is set on board piece 2 or heterogeneous piece 102A, 102B as shown in FIG. 22, and a terminal of electronic component 49 is connected to wiring layers 22₃, 32₃, 122₃, 132₃ of rigid wiring board 20₃, 30₃, 120₃, 130₃ forming the outermost layer of first and second rigid parts 20, 30, 120, 130, whereby electronic component 49 is mounted on composite wiring board 71.

In this state, electronic components 49 can be electrically connected to each other or to an external circuit when board piece 2 or heterogeneous piece 102A, 102B is connected to the external circuit.

In the flexible wiring boards 10, 110, 8A, 8B described above, base films 11, 111, 51 and cover films 16, 116, 56 are polyimide films of ten to several tens of micrometers.

Wiring layers 12, 112, 52 of flexible wiring boards 10, 110, 8A, 8B and wiring layers 22₁-22₃, 32₁-32₃, 122₁-122₃, 132₁-132₃ of rigid wiring boards 20₁-20₃, 30₁-30₃, 120₁-120₃, 130₁-130₃ comprise a copper foil having a thickness of ten to several tens of micrometers patterned in a predetermined configuration.

Thus, wiring layers 12, 112, 52 of flexible wiring boards 10, 110, 8A, 8B are bent with base films 11, 111, 51 or cover films 16, 116, 56 to ensure the flexibility of flexible wiring boards 10, 110, 8A, 8B.

On the other hand, base substrates 21₁-21₃, 31₁-31₃, 121₁-121₃, 131₁-131₃ of rigid wiring boards 20₁-20₃, 30₁-30₃, 120₁-120₃, 130₁-130₃ are inflexible thin plates having a thickness of about 50-500 μm made from glass epoxy resins or the like.

Once electronic component 49 is mounted on board piece 2 or heterogeneous piece 102A, 102B, therefore, no stress is imposed between the terminal of electronic component 49 and board piece 2 or heterogeneous piece 102 even if flexible wiring board 10, 8A, 8B is bent.

Next, another example of a board piece is explained. Reference 3 in FIG. 23 represents a board piece according to a second example. An end portion of cover film 46 of flexible wiring board 40 forming a part of this board piece 3 is not adhered to wiring layer 12 or base film 11 so that when the end of cover film 46 is lifted, the surface of wiring layer 12 is exposed and another film can be inserted between cover film 46 and wiring layer 12.

Cover film 46 of this flexible wiring board 40 on one or both of stages 42₁, 42₂ is longer than cover film 16 of flexible wiring board 10 of board piece 2 shown in FIG. 15 and an end portion of cover film 46 projects from stage 42₁, 42₂. Here, it projects from one stage 42₁, but not from the other stage 42₂.

The other structures of this board piece 3 are the same as those of board piece 2 according to the first example.

FIG. 24 shows that this board piece 3 and heterogeneous piece 102A have been connected via connecting flexible wiring board 8A. During connection, cover film 46 of board piece 3 is lifted and an anisotropically conductive film 17 is placed on wiring layer 12, and an end of connecting flexible wiring board 8A is inserted between anisotropically conductive film 17 and cover film 46, whereby wiring layer 52 of connecting flexible wiring board 8A is electrically connected to wiring layer of flexible wiring board 10 via anisotropically conductive film 17.

The part of cover film 46 projecting from base film 11 is placed on connecting flexible wiring board 8A and adhered to base film 51 of connecting flexible wiring board 8A with an adhesive. Thus, flexible wiring board 10 of board piece 3 and connecting flexible wiring board 8A are mechanically connected via cover film 46 rather than a reinforcing film.

The end of cover film 46 on the side of board piece body 41 may extend into board piece body 41 or terminate at the boundary between stage 42₁ and board piece body 41.

Stage 42₂ on the opposite side to the stage 42₁ described above is connected to a heterogeneous piece not shown via connecting flexible wiring board 8B by the same procedure as described for the first example to obtain a composite wiring board 72 according to a second example of various exemplary embodiments.

Then, an electronic component is set on board piece 3 or heterogeneous piece 102A or the like of composite wiring board 72 according to the second example and a terminal of the electronic component is connected to wiring layers 22₃, 32₃, 122₃, 132₃ of the outermost rigid wiring board 20₃, 30₃, 120₃, 130₃, whereby the electronic component is mounted on composite wiring board 72.

When board piece 3 or heterogeneous piece 102A is connected to an external circuit in this state, the mounted electronic component is connected to the external circuit.

Although cover film 46 on only one stage 42₁ is separated from base film 11 in the composite wiring board 72 described above, such cover film 46 may be provided on both stages 42₁, 42₂. In this case, both or one of cover films 46 can be of the length projecting from stage 42₁, 42₂.

Although heterogeneous piece 102 had a flexible wiring board 110 in each embodiment described above, composite wiring boards of various exemplary embodiments may use a heterogeneous piece having no flexible wiring board and such heterogeneous piece and a board piece may be connected via connecting flexible wiring board 8A (or 8B).

Composite wiring boards combining the heterogeneous piece 102 having a flexible wiring board 110 described above and a heterogeneous piece having no flexible wiring board with a board piece 2 of various exemplary embodiments are also included.

Moreover, composite wiring boards of various exemplary embodiments can also be formed, wherein connecting flexible wiring board 8A, 8B forms a part of a heterogeneous piece.

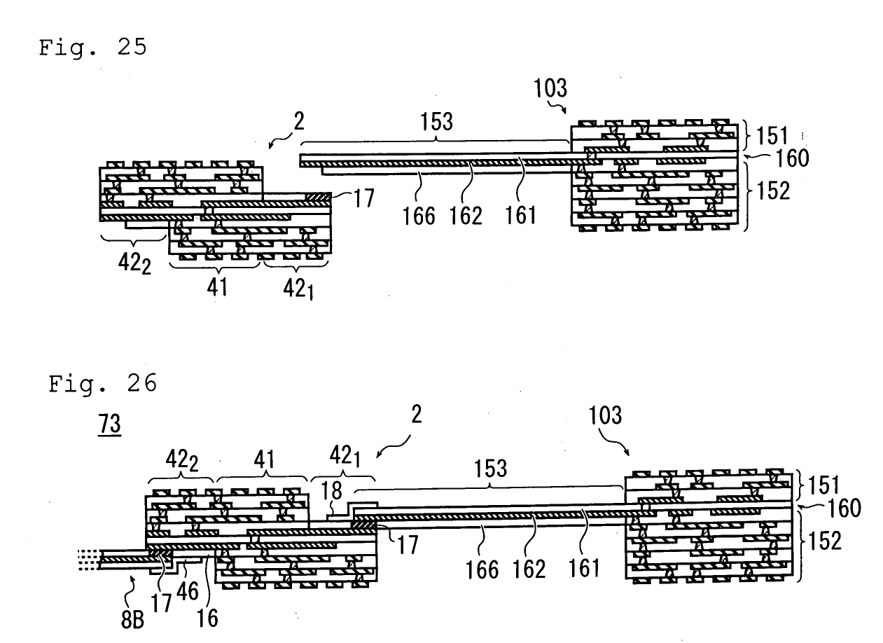

Reference 103 in FIG. 25 represents an example of the heterogeneous piece used in such a case, and this heterogeneous piece 103 comprises a long flexible wiring board 160 and a first and a second stacks 151, 152.

First and second stacks 151, 152 comprise one or more stacked rigid wiring boards shorter than flexible wiring board 160 and first and second stacks 151, 152 are provided on one surface and the opposite surface of flexible wiring board 160 on the same end and stacks 151, 152 and flexible wiring board 160 are fixed to each other with an adhesive.

As flexible wiring board 160 is longer than stacks 151, 152, flexible wiring board 160 projects from between stacks 151, 152. Reference 153 in the same figure represents such projection.

Flexible wiring board 160 comprises a stack of a base film 161, a patterned wiring layer 162 and a cover film 166, and cover film 166 is partially removed at an end of projection 153 to expose the top of wiring layer 162.

Then, an anisotropically conductive film 17 is placed on the end of flexible wiring board 10 on the side of one stage 42₁ of board piece 2 of various exemplary embodiments and an end of flexible wiring board 160 of the heterogeneous piece 103 described above is adhered to anisotropically conductive film 17.

When the other stage 42₂ is connected to heterogeneous piece 102B or the like via connecting flexible wiring board 8B, long flexible wiring board 160 of heterogeneous piece 103 functions as a connecting flexible wiring board to obtain a composite wiring board 73 according to a third example of various exemplary embodiments.

A reinforcing film 18 can be applied across base film 161 at an end of flexible wiring board 160 of heterogeneous piece 103 and cover film 16 of flexible wiring board 10 of board piece 2.

Two heterogeneous pieces 103 having flexible wiring board 160 partially projecting from between stacks 151, 152 can be used and projection 153 can be connected to both of two stages 42₁, 42₂ of board piece 2, or board piece 2 can be combined with another heterogeneous piece to form a composite wiring board.

In this composite wiring board 73, an electronic component can also be mounted on each board piece 2 or heterogeneous piece 103.

As has been described above, board piece 2 of various exemplary embodiments can be freely combined with heterogeneous pieces to form composite wiring boards. Any composite wiring board is included in various exemplary embodiments so far as a board piece of various exemplary embodiments is used. Heterogeneous pieces that can form composite wiring boards of various exemplary embodiments may comprise flexible wiring boards or rigid wiring boards alone without flexible wiring board.

The electronic component 49 described above may be mounted after a composite wiring board of various exemplary embodiments has been assembled from board pieces, or the electronic component may be mounted on board piece 2 and then connected to connecting flexible wiring board 8A, 8B or flexible wiring boards 110, 160 of heterogeneous pieces 102, 103 to assemble a composite wiring board.

Although the flexible wiring boards 8A, 8B used for the connection and the flexible wiring board 10 included in stages 42₁, 42₂ of a board piece were single-layer components, a plurality of flexible wiring boards may be stacked. Flexible wiring board 110, 160 included in heterogeneous pieces 102, 103 can also be formed by stacking a plurality of flexible wiring boards.

Board pieces of various exemplary embodiments can be more easily stored and handled than composite wiring boards because composite wiring boards can be assembled from board pieces or heterogeneous pieces before use.

1. A board piece, comprising: at least one flexible wiring board; a plurality of short rigid wiring boards being stacked together shorter than the flexible wiring board; and a plurality of long rigid wiring boards being stacked together longer than the short rigid wiring boards, wherein
the stacked short rigid wiring boards are provided on one surface of the flexible wiring board, the stacked long rigid wiring boards are provided on the opposite surface, and the one surface of the flexible wiring board is exposed.

2. The board piece of claim 1, wherein an end portion of the flexible wiring board is not fixed to the long rigid wiring boards.

3. The board piece of claim 1, wherein wiring layers of adjacent ones of the short rigid wiring boards are connected via conductive bumps and wiring layers of adjacent ones of the long rigid wiring boards are connected via conductive bumps.

4. A composite wiring board comprising a connecting flexible wiring board and two or more board pieces, wherein
each of the board pieces has at least one flexible wiring board; a plurality of short rigid wiring boards being stacked together shorter than the flexible wiring board; and a plurality of long rigid wiring boards being stacked together longer than the short rigid wiring boards,
the stacked short rigid wiring boards are provided on one surface of the flexible wiring board,
the stacked long rigid wiring boards are provided on the opposite surface, the one surface of the flexible wiring board is exposed, and
the exposed portion of the flexible wiring board of each of the board pieces is connected to an end of the connecting flexible wiring board.

5. The composite wiring board of claim 4, wherein a reinforcing film is applied across the connecting flexible wiring board and the flexible wiring board of the board piece.

6. A composite wiring board, comprising a first board piece and a second board piece, wherein
the first board piece has at least one flexible wiring board; a plurality of short rigid wiring boards being stacked together shorter than the flexible wiring board; and a plurality of long rigid wiring boards being stacked together longer than the short rigid wiring boards,
the stacked short rigid wiring boards are provided on one surface of the flexible wiring board,
the stacked long rigid wiring boards are provided on the opposite surface,
the one surface of the flexible wiring board is exposed,
the second board piece has at least one flexible wiring board and a plurality of rigid wiring boards being stacked together,
an end of the flexible wiring board projects from an overlap between the flexible wiring board and the rigid wiring boards,
both surfaces of the end of the flexible wiring board are exposed, and
the exposed portion of the flexible wiring board of the first board piece and the exposed portion of the flexible wiring board of the second board piece are connected.

7. The composite wiring board of claim 6, wherein a reinforcing film is applied across the exposed portion of the flexible wiring board of the first board piece and the exposed portion of the flexible wiring board of the second board piece.

8. The composite wiring board of claim 6, wherein an electronic component is mounted on at least one of the board pieces.

9. A board piece, comprising: a first and a second rigid parts having a rigid wiring board; and a flexible wiring board longer than the first and second right part, wherein
the first rigid part and the second rigid part are provided on one surface and the opposite surface of the flexible wiring board in such a relative position that one of the rigid parts projects from the other,
the center portion of the flexible wiring board is sandwiched between the first and second rigid parts so that the flexible wiring board and the first and second rigid parts are fixed to each other at the center portion of the flexible wiring board, and
the flexible wiring board projects from the center portion on both of the first rigid part and the second rigid part.

10. The board piece of claim 9, wherein at least one of the projecting parts of the flexible wiring board on the first and second rigid parts is separable from the first or second rigid part.

11. The board piece of claim 9, wherein the flexible wiring board comprises a base film having flexuosity and a patterned wiring layer provided on each surface of the base film.

12. The board piece of claim 9, wherein the rigid wiring boards forming the first and second rigid parts comprises a hard board and a patterned wiring layer provided on at least one surface of the hard board and the wiring layer of the flexible wiring board and the rigid wiring board adjacent to the flexible wiring board are electrically connected to each other via conductive bumps.

13. The board piece of claim 9, wherein at least one of the first and second rigid parts comprises two or more rigid wiring boards being stacked and the patterned wiring layers of the stacked rigid wiring boards are connected to each other via conductive bumps.

14. A composite wiring board, comprising a heterogeneous piece having at least a rigid wiring board; a board piece; and a connecting flexible wiring board, wherein
the board piece has a first and a second rigid parts having a rigid wiring board; and a flexible wiring board longer than the first and second rigid part,
the first rigid part and the second rigid part are provided on one surface and the opposite surface of the flexible wiring board in such a relative position that one of the rigid parts projects from the other,
the center portion of the flexible wiring board is sandwiched between the first and second rigid parts so that the flexible wiring board and the first and second rigid parts are fixed to each other at the center portion of the flexible wiring board,
the flexible wiring board projects from the center portion on both of the first rigid part and the second rigid part,
an end portion of the flexible wiring board of the board piece is adhered to one end of the connecting flexible wiring board,
the other end of the connecting flexible wiring board is adhered to the heterogeneous piece, and
the wiring layer of the flexible wiring board of the board piece and the wiring layer of the heterogeneous piece are electrically connected via the wiring layer of the connecting flexible wiring board.

15. The composite wiring board of claim 14, wherein a reinforcing film is applied across the connecting flexible wiring board and the flexible wiring board of the board piece.

16. The composite wiring board of claim 14, wherein an electronic component is mounted on the board piece.
